(19) United States
(12) Patent Application Publication
(10) Pub. No.: US 2013/0002096 A1
(43) Pub. Date: Jan. 3, 2013

(54) PIEZOELECTRIC VIBRATING DEVICE AND METHOD FOR MANUFACTURING SAME

(75) Inventors: MITOSHI UMEKI, SAITAMA (JP); RYOICHI ICHIKAWA, SAITAMA (JP)

(73) Assignee: NIHON DEMPA KOGYO CO., LTD., TOKYO (JP)

(21) Appl. No.: 13/533,979

(22) Filed: Jun. 27, 2012

(30) Foreign Application Priority Data
Jun. 30, 2011 (JP) 2011-145285

(51) Int. Cl. H01L 41/053; H01L 41/047

(52) U.S. Cl. 310/344; 29/25.35

(57) ABSTRACT

A piezoelectric device includes a piezoelectric vibrating plate, a first plate, a first glass sealing material disposed in a ring shape, and an electrically conductive adhesive. The piezoelectric vibrating plate includes a piezoelectric vibrating piece, a frame body, and a pair of extraction electrodes. The piezoelectric vibrating piece includes a pair of excitation electrodes. The frame body surrounds the piezoelectric vibrating piece. The frame body is formed integrally with the piezoelectric vibrating piece. The first glass sealing material encloses a periphery of the first main surface of the frame body so as to bond the first plate and the first main surface of the frame body together.

### CROSS-REFERENCE TO RELATED APPLICATIONS

This application claims the priority benefit of Japan application serial no. 2011-145285, filed on Jun. 30, 2011. The entirety of the above-mentioned patent application is hereby incorporated by reference herein and made a part of this specification.

### FIELD

This disclosure pertains to, inter alia, methods for manufacturing piezoelectric vibrating devices in which unwanted gas inside their packages are ventilated when lids, bases, and vibrating pieces are fabricated on a wafer scale. The disclosure also pertains to piezoelectric vibrating devices produced by such methods.

### DESCRIPTION OF THE RELATED ART

A piezoelectric device is required to be further downsized. Japanese Unexamined Patent Application Publication No. 2010-109528 proposes the following technique as a technique to achieve mass production. For example, this technique sandwiches a piezoelectric wafer, which has a piezoelectric vibrating piece, between a lid wafer and a base wafer which each have a shape similar to a shape of the piezoelectric wafer, in a vertical direction so as to bond the three layers of substrate together.

In this technique, to connect electrodes of the piezoelectric wafer and the base wafer together, the electrodes are formed on surfaces of resin protrusions with flexibility. This ensures conduction through the protruding electrodes. The piezoelectric wafer, the lid wafer, and the base wafer are bonded by plasma activated bonding.

Disadvantageously, plasma activated bonding requires large equipment, and a facilitated method is desired to bond the piezoelectric wafer, the lid wafer, and the base wafer together. The facilitated method also requires assured electrical connection between the electrodes of the piezoelectric wafer and the base wafer. Further, removing harmful gas and water inside the piezoelectric device is required to ensure product stability of the piezoelectric device.

Therefore, there is a need for methods for manufacturing piezoelectric devices, as disclosed herein, that ensure electrical connection between electrodes and do not result in entrapment of harmful gas and water inside the piezoelectric device. There is also a need for piezoelectric devices that do not contain harmful gas and water.

### SUMMARY

A first aspect of the present invention is directed to a piezoelectric device. The piezoelectric device includes a piezoelectric vibrating plate, a first plate, a first glass sealing material disposed in a ring shape, and an electrically conductive adhesive. The piezoelectric vibrating plate includes a piezoelectric vibrating piece, a frame body, and a pair of extraction electrodes. The piezoelectric vibrating piece includes a pair of excitation electrodes. The frame body surrounds the piezoelectric vibrating piece. The frame body is formed integrally with the piezoelectric vibrating piece. The frame body includes a first main surface and a second main surface. The pair of extraction electrodes are extracted from the pair of excitation electrodes to the first main surface of the frame body. The first plate includes a first surface and a second surface. The first surface includes a pair of external electrodes. The second surface includes a pair of connecting electrodes. The pair of connecting electrodes are electrically connected to the pair of the external electrodes. The second surface bonds to the first main surface. The first glass sealing material encloses a periphery of the first main surface of the frame body so as to bond the first plate and the first main surface of the frame body together. The electrically conductive adhesive electrically connects the pair of the extraction electrodes to the pair of the connecting electrodes.

A second aspect of the present invention is directed to a method for manufacturing the above-describe piezoelectric device. The method includes preparing a piezoelectric wafer, preparing a first wafer, applying first glass sealing material, calcinating, applying electrically conductive adhesive, and bonding. The piezoelectric wafer includes a plurality of piezoelectric vibrating plates. The piezoelectric vibrating plate includes a piezoelectric vibrating piece, a frame body, and a pair of extraction electrodes. The piezoelectric vibrating piece includes a pair of excitation electrodes. The frame body surrounds the piezoelectric vibrating piece. The frame body is formed integrally with the piezoelectric vibrating piece. The frame body includes a first main surface and a second main surface. The pair of extraction electrodes are extracted from the pair of excitation electrodes to the first main surface of the frame body. The first wafer includes a plurality of first plates. The first plate includes a first surface and a second surface. The first surface includes a pair of external electrodes. The second surface includes a pair of connecting electrodes. The second surface is at an opposite side of the first surface. The first wafer includes a through-hole and a side-surface electrode. The through-hole passes through the first surface and the second surface between the adjacent first plates. The side-surface electrode electrically connects the external electrodes to the connecting electrodes at the through-hole. The applying first glass sealing material applies first glass sealing material on at least one of the frame body and a peripheral area of the first plate. The calcinating calcinates the first applied glass sealing material. The applying electrically conductive adhesive applies electrically conductive adhesive on at least one of the extraction electrodes and the connecting electrodes after the calcinating. The bonding bonds the piezoelectric wafer and the first wafer together after the applying the electrically conductive adhesive.

The piezoelectric device according to the first aspect of the present invention vibrates or oscillates with high stability due to the absence of harmful gas or water. The manufacturing method according to the second aspect of the present invention ensures electrical connection between the electrodes and does not entrap harmful gas and water inside the piezoelectric device.

### BRIEF DESCRIPTION OF THE DRAWINGS

FIG. 1 is an exploded perspective view of a first piezoelectric device according to a first embodiment of the present invention.

FIG. 2A is a cross-sectional view taken along the line A-A′ of FIG. 1 after bonding of a first quartz-crystal frame, a first base, and a first lid according to the first embodiment.

FIG. 2B is a plan view illustrating a sealing material formed on the first base according to the first embodiment.

FIG. 2C is a plan view illustrating a sealing material formed on the first base according to the first embodiment.

FIG. 3 is a flowchart of manufacture of the first piezoelectric device according to the first embodiment.

FIG. 4 is a plan view of a quartz-crystal wafer according to the first embodiment.

FIG. 5 is a plan view of a base wafer according to the first embodiment.

FIG. 6 is a plan view of a lid wafer according to the first embodiment.

FIG. 7 is an exploded perspective view of a second piezoelectric device according to a second embodiment of the present invention.

FIG. 8 is a plan view of a quartz-crystal wafer according to the second embodiment.

FIG. 9 is a plan view of a base wafer according to the second embodiment.

FIG. 10 is an exploded perspective view of a third piezoelectric device according to a third embodiment of the present invention.

FIG. 11 is a plan view of a quartz-crystal wafer according to the third embodiment.

### DETAILED DESCRIPTION

Each embodiment of the present invention is described below by referring to the accompanying drawings. In the following embodiments, an AT-cut quartz crystal piece, which has a thickness-shear vibration mode, is used as a piezoelectric vibrating piece. Here, the AT-cut quartz crystal piece has a principal surface (in the XZ plane) that is tilted by 35° 15′ about the Y-axis of the crystal coordinate system (XYZ) in the direction from the Z-axis to the Y-axis around the X-axis. Therefore, in the first embodiment, the longitudinal direction of the first piezoelectric device 100 is referred as the X-axis direction, the height direction of the first piezoelectric device 100 is referred as the Y′-axis direction, and the direction perpendicular to the X-axis and Y′-axis directions is referred as the Z′-axis direction. This definition is similar in a second embodiment and a third embodiment below.

### Overall Configuration of a First Piezoelectric Device 100 According to a First Embodiment

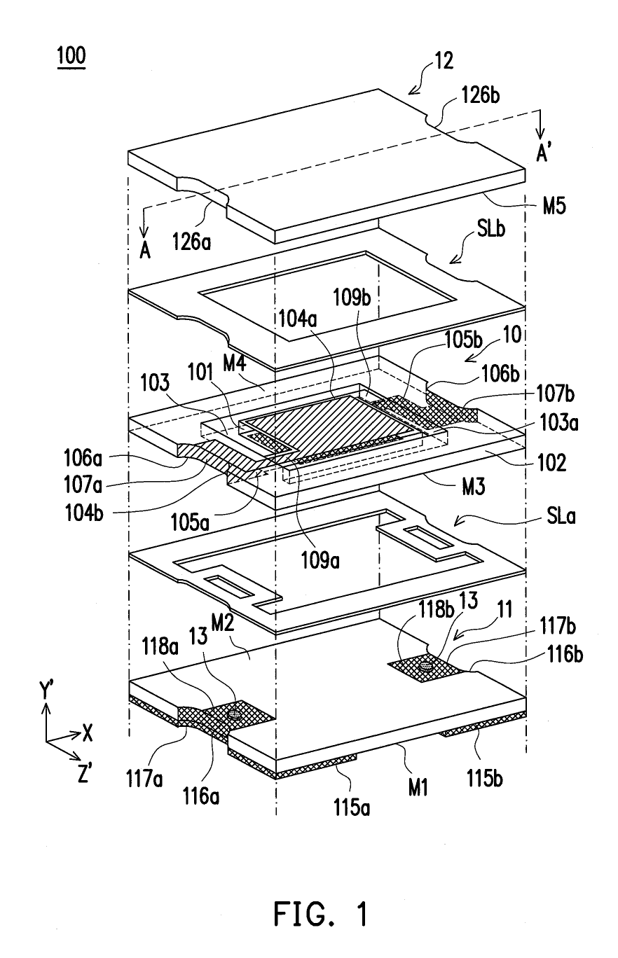

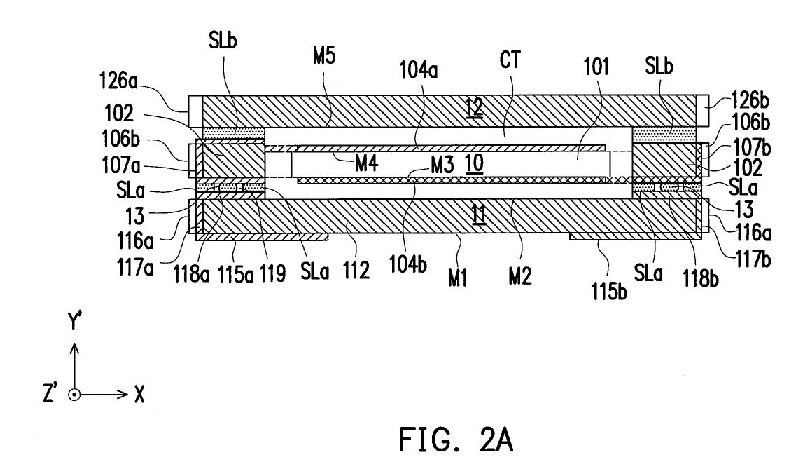

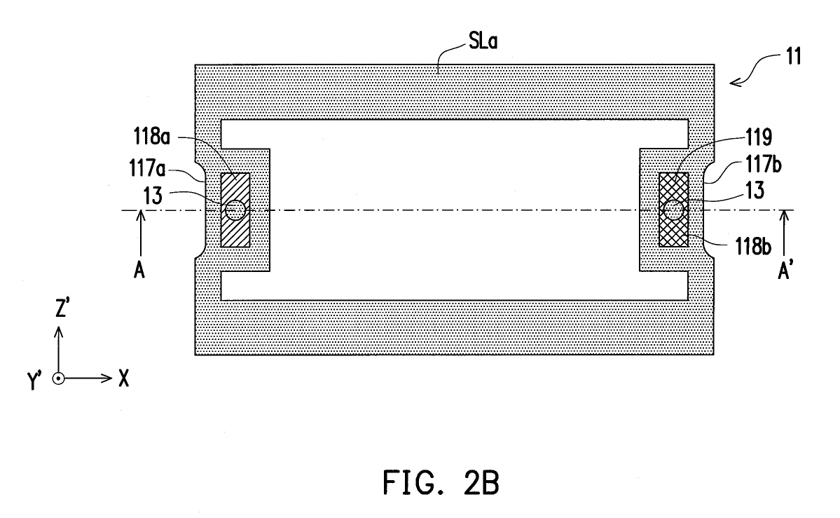

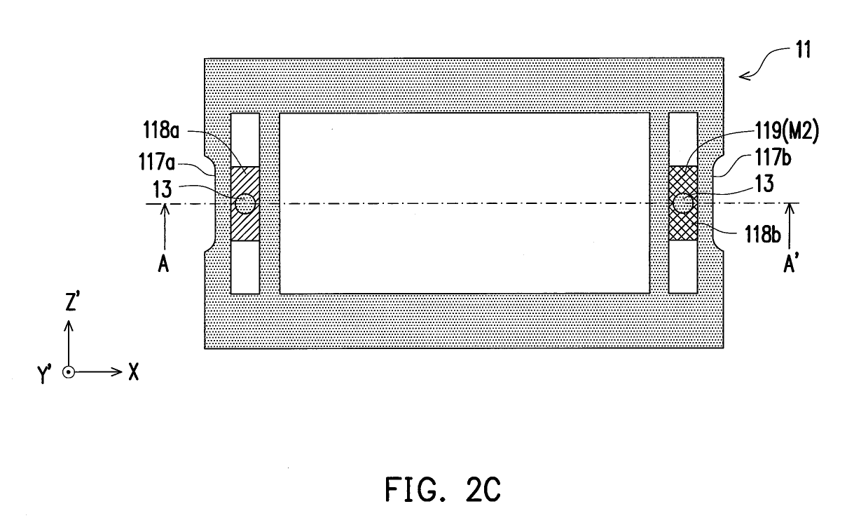

The overall configuration of the first piezoelectric device 100 is described below by referring to FIGS. 1, 2A, 2B, and 2C. FIG. 1 is an exploded perspective view of the first piezoelectric device 100 from a first lid 12 side. FIG. 2A is a cross-sectional view taken along the line A-A′ of FIG. 1 after bonding the first quartz-crystal frame 10, a first base 11, and a first lid 12 together. FIG. 2B is a plan view illustrating a sealing material SLa formed on the first base 11. FIG. 2C is a modification of FIG. 2B, and is a plan view illustrating a sealing material SLc formed on the first base 11.

As illustrated in FIGS. 1 and 2A to 2C, the first piezoelectric device 100 includes the AT-cut first quartz-crystal frame 10, the first base 11, and the first lid 12. The first base 11 and the first lid 12 are each made of a quartz-crystal material. The first quartz-crystal frame 10 and the first base are bonded together by the sealing material SLa, while the first quartz-crystal frame 10 and the first lid 12 are bonded together by the sealing material SLb. The first base 11 and the first lid 12 are bonded to the first quartz-crystal frame 10 so as to form a cavity CT (see FIG. 2A). The cavity CT is in a vacuum state or filled with inert gas.

The first quartz-crystal frame 10 includes an AT-cut quartz-crystal material. The first quartz-crystal frame 10 includes a crystalline bonding surface M3 at the −Y′ axis side and a crystalline bonding surface M4 at +Y′ axis side. The first quartz-crystal frame 10 includes a quartz-crystal vibrating portion 101 and a frame portion 102, which surrounds the quartz-crystal vibrating portion 101. An L-shaped void 103, which passes through in the thickness direction of the first quartz-crystal frame 10, is formed between the quartz-crystal vibrating portion 101 and the frame portion 102. Portions where the void 103 is not formed constitute joining portions 109a and 109b between the quartz-crystal vibrating portion 101 and the frame portion 102. Excitation electrodes 104a and 104b are formed on the respective main surfaces of the quartz-crystal vibrating portion 101 (see FIGS. 1 and 2A). Extraction electrodes 105a, 105b, which are connected to the excitation electrodes 104a and 104b, are formed on the respective surfaces of the frame portion 102 (see FIG. 1).

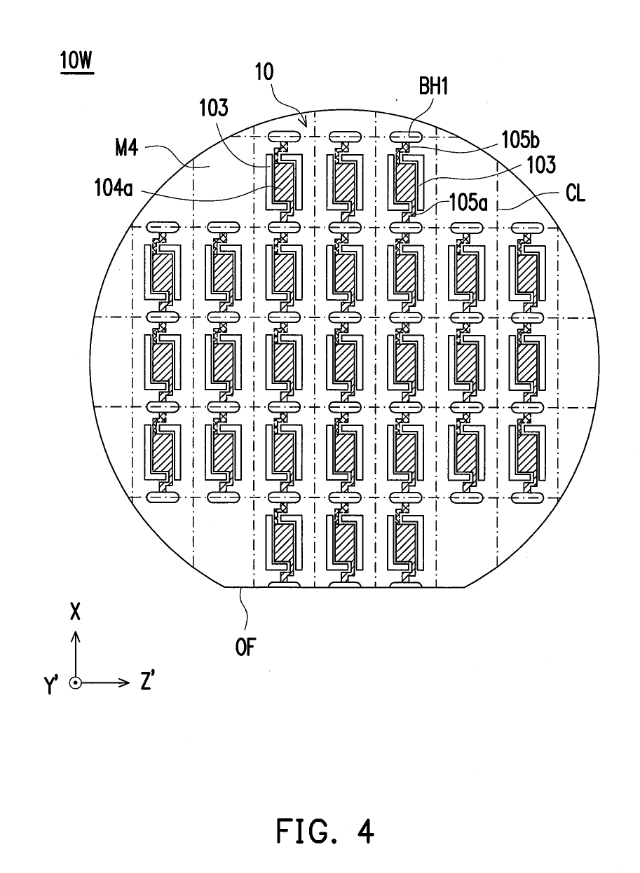

Further, quartz-crystal castellations 106a and 106b are formed at both sides of the first quartz-crystal frame 10 in the X axis direction. A quartz-crystal side-surface electrode 107a is formed at the quartz-crystal castellation 106a. The quartz-crystal side-surface electrode 107a is connected to the extraction electrode 105a. Similarly, a quartz-crystal side-surface electrode 107b is formed at the quartz-crystal castellation 106b. The quartz-crystal side-surface electrode 107b is connected to the extraction electrode 105b. The quartz-crystal castellations 106a and 106b are formed when rounded-rectangular through-holes BH1 are diced (see FIG. 4).

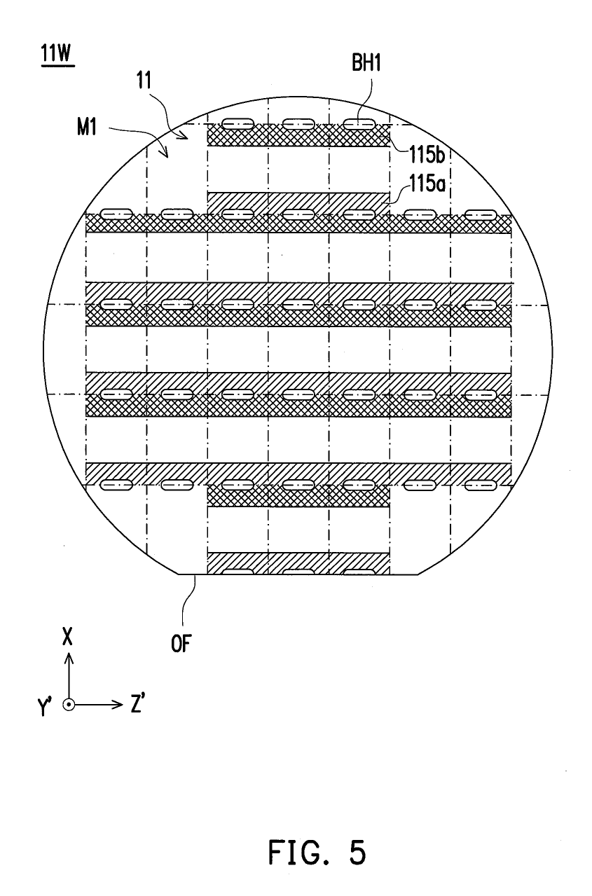

The first base 11 includes a mounting surface M1 and a bonding surface M2. A pair of external electrodes 115a and 115b are formed on the mounting surface M1 of the first base 11. Side castellations 116a and 116b are formed at both sides of the first base 11 in the X axis direction. A side-surface electrode 117a, which is connected to the external electrodes 115a, is formed at the side castellation 116a. A side-surface electrode 117b, which is connected to the external electrodes 115b, is formed at the side castellation 116b. A connecting electrode 118a, which is connected to the side-surface electrode 117a, is formed on the bonding surface M2. A connecting electrode 118b is formed on the side-surface electrode 117b. The side castellations 116a and 116b are formed when the rounded-rectangular through-holes BH1 are diced (see FIG. 5).

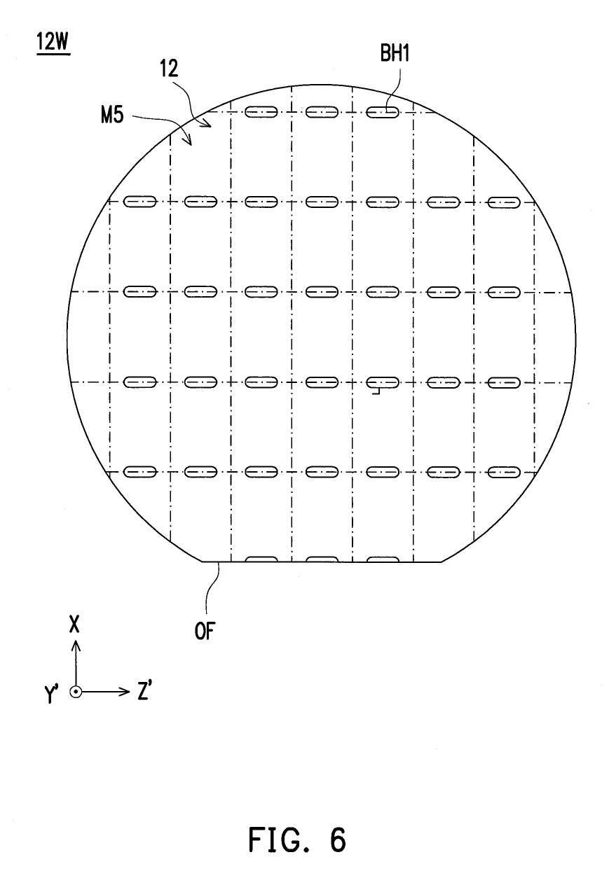

The first lid 12 includes a bonding surface M5. Side castellations 126a and 126b are formed at both sides of the first lid 12 in the X axis direction. The side castellations 126a and 126b are formed when the rounded-rectangular through-holes BH1 are diced (see FIG. 6).

The sealing materials SLa and SLb are made of low-melting-point glass containing, for example, vanadium. While the sealing materials SLa and SLb are each illustrated in a sheet shape, the sealing materials SLa and SLb may be formed by applying sealing material. That is, the sealing material SLa may be formed by applying sealing material over the bonding surface M2 of the first base 11 or the crystalline bonding surface M3. The sealing material SLb may be formed by applying sealing material over the crystalline bonding surface M4 or the bonding surface M5 of the first lid 12.

The sealing materials SLa and SLb is made of the low-melting-point glass, which is resistant to water and humidity. This prevents water in the air from entering the cavity and also prevents degradation of vacuum in the cavity. The low-melting-point glass is lead-free vanadium-based glass that melts at temperatures of 350 to 400° C. The vanadium-based glass is formulated as a paste mixed with binder and solvent. The vanadium-based glass bonds to another member by firing and cooling. The vanadium-based glass has high reliability in, for example, air tightness at bonding and resistance to water and humidity. Further, controlling glass structure of the vanadium-based glass flexibly controls coefficient of thermal expansion.

As illustrated in FIG. 2A, the sealing material SLa is applied between the bonding surface M2 of the first base 11 and the crystalline bonding surface M3 of the frame portion 102 of the first quartz-crystal frame 10. The sealing material SLa bonds the first quartz-crystal frame 10 and the first base 11 together. The sealing material SLb is applied between the bonding surface M5 of the first lid 12 and the crystalline bonding surface M4 of the first quartz-crystal frame 10. The sealing material SLb bonds the first quartz-crystal frame 10 and the first lid 12 together. Thus, the first quartz-crystal frame 10, the first base 11, and the first lid 12 are bonded together.

As illustrated in FIG. 2B, the first base 11 includes the connecting electrode 118a and the connecting electrode 118b on the bonding surface M2. The connecting electrode 118a is electrically connected to the external electrodes 115a and the side-surface electrode 117a. The connecting electrode 118b is electrically connected to the external electrodes 115b and the side-surface electrode 117b. An electrically conductive adhesive 13 is formed at each of the connecting electrodes 118a and 118b. While one electrically conductive adhesive 13 is placed at each electrode in FIG. 2B, a plurality of electrically conductive adhesive 13 may be placed at each electrode.

As illustrated in FIGS. 2A and 2B, the sealing material SLa covers and surrounds an outer periphery of the connecting electrode 118a and the connecting electrode 118b on the bonding surface M2, so as to form a space 119, which encloses the electrically conductive adhesives 13. In this configuration, the first base 11 and the first quartz-crystal frame 10 are heated to between 300 and 400° C. in nitrogen gas or in a vacuum, and then pressed. This allows the sealing material SLa and the electrically conductive adhesive 13 to bond the first quartz-crystal frame 10 and the first base 11 together, and also electrically connect the extraction electrodes 105a and 105b of the first quartz-crystal frame 10 to the connecting electrodes 118a and 118b at the same time. In view of this, the cavity CT, which is formed of the first quartz-crystal frame 10, the first base 11, and the first lid 12, keeps air tightness from the outside. This prevents gas that is released from the electrically conductive adhesives 13 from entering into the cavity CT.

FIG. 2C illustrates a modification of the sealing material SL. The sealing material SLc has spaces 119 with large regions to each enclose the electrically conductive adhesive 13. The sealing material SLa illustrated in FIG. 2B is formed along the outer peripheries of the connecting electrode 118a and the connecting electrode 118b. In contrast, the sealing material SLc illustrated in FIG. 2C is formed to surround the connecting electrode 118a and the connecting electrode 118b, and their peripheral areas. A method for manufacturing the first piezoelectric device 100

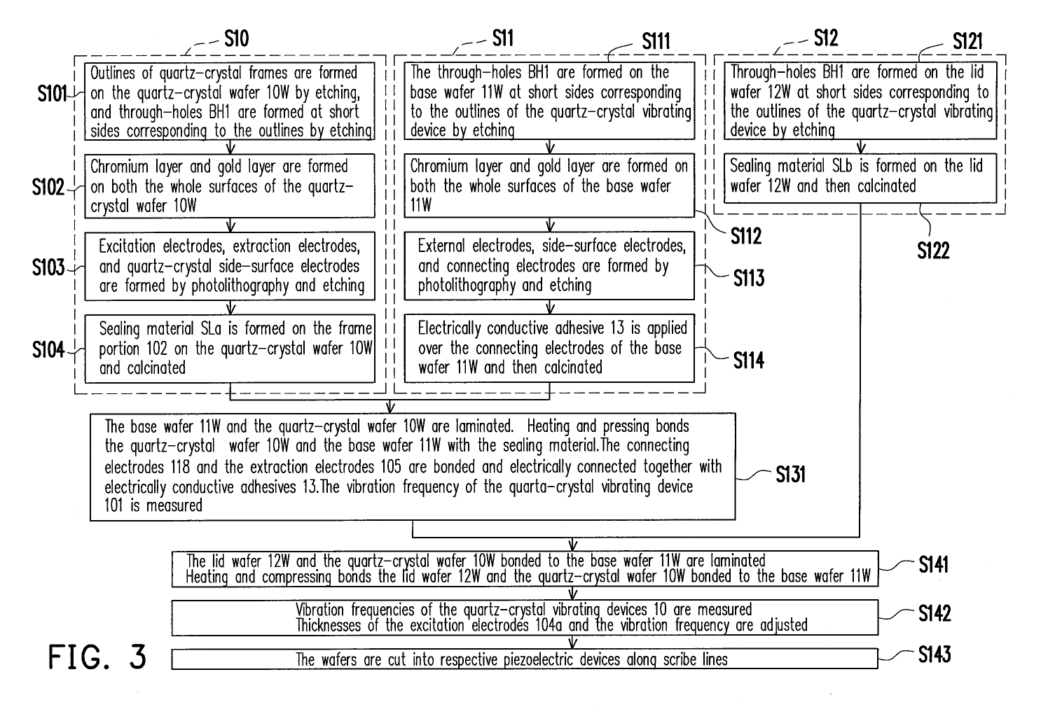

FIG. 3 is a flowchart illustrating manufacture of the first piezoelectric device 100. FIG. 4 is a plan view of a quartz-crystal wafer 10W. FIG. 5 is a plan view of a base wafer 11W. FIG. 6 is a plan view of a lid wafer 12W.

In step S10, the first quartz-crystal frame 10 is manufactured. Step S10 includes steps S101 to S104. In step S101, outlines of a plurality of first quartz-crystal frames 10 are formed on the quartz-crystal wafer 10W (see FIG. 4) by etching. This forms the quartz-crystal vibrating portion 101, the frame portion 102, and the void 103 (see FIG. 1). This also forms the rounded-rectangular through-holes BH1, which pass through the quartz-crystal wafer 10W, at the short sides of respective first quartz-crystal frames 10 as illustrated in FIG. 4. Dividing the rounded-rectangular through-holes BH1 into two provides one of the castellations 106a and 106b (see FIG. 1) for each of the first piezoelectric devices 100.

In step S102, a chromium layer and a gold layer are sequentially formed on the quartz-crystal wafer 10W on its both surfaces and inside the rounded-rectangular through-holes BH1 by sputtering or vacuum-deposition. Here, the chromium layer as a foundation has exemplary thicknesses of 0.05 to 0.1 μm, while the gold layer has exemplary thicknesses of 0.2 to 2 μm.

In step S103, photoresist is uniformly applied over a whole surface of the metal layer. Patterns of the excitation electrodes 104a and 104b, the extraction electrodes 105a and 105b, and the quartz-crystal side-surface electrodes 107a and 107b, which are formed on a photomask, are exposed onto the quartz-crystal wafer 10W by using an exposure device (not shown). Next, exposed regions of the metal layer where the photoresist is removed are etched. As illustrated in FIGS. 1 and 2A to 2C, the excitation electrodes 104a and 104b and the extraction electrodes 105a and 105b are formed on both surfaces of the quartz-crystal wafer 10W, and the quartz-crystal side-surface electrodes 107a and 107b are formed at the rounded-rectangular through-holes BH1.

In step S104, the sealing material SLa is uniformly formed on the surface M3 of the frame portion 102 on the quartz-crystal wafer 10W (see FIG. 1). For example, the sealing material SLa, which is made of low-melting-point glass, is formed on the surface M3 of the frame portion 102 on the quartz-crystal wafer 10W by screen-printing and calcinated. The sealing material SLa may be formed on the surface M2 of the base wafer 11W (see FIG. 1).

In step S11, the first base 11 is fabricated. Step S11 includes steps S111 to S114. In step S111, the base wafer 11W is prepared. Then, the rounded-rectangular through-holes BH1 are formed to pass through the base wafer 11W on both sides of the base wafer 11W in the X axis direction by etching (see FIG. 5). Dividing the rounded-rectangular through-holes BH1 into two provides one of the castellations 116a and 116b for each of the first piezoelectric devices 100 (see FIG. 1).

In step S112, a chromium layer and a gold layer are sequentially formed on the base wafer 11W on the mounting surface M1 and inside the rounded-rectangular through-holes BH1 by sputtering or vacuum-deposition. Here, the chromium layer as a foundation has exemplary thicknesses of 0.05 to 0.1 μm, while the gold layer has exemplary thicknesses of 0.2 to 2 μm.

In step S113, photoresist is uniformly applied over the metal layer. Patterns of the external electrodes 115a and 115b, the side-surface electrodes 117a and 117b, and the connecting electrodes 118a and 118b, which are formed on a photomask, are exposed onto the base wafer 11W by using an exposure device (not shown). Next, exposed regions of the metal layer where the photoresist is removed are etched. As illustrated in FIGS. 1 and 2A to 2C, the external electrodes 115a and 115b are formed on the mounting surface M1 of the base wafer 11W. The side-surface electrodes 117a and 117b are formed at the rounded-rectangular through-holes BH1. The connecting electrodes 118a and 118b are formed on the base bonding surface M2.

In step S114, the electrically conductive adhesive 13 is applied over or placed on the connecting electrodes 118a and 118b of the base wafer 11W, and then calcinated. Gas released from the electrically conductive adhesives 13 is eliminated by the calcination.

In step S12, the first lid 12 is fabricated. Step S12 includes steps S121 and S122. In step S121, the lid wafer 12W is prepared. Then, the rounded-rectangular through-holes BH1 are formed to pass through the lid wafer 12W at the short sides of the lid wafer 12W by etching (see FIG. 6). Dividing the rounded-rectangular through-holes BH1 into two provides the castellations 126a and 126b for each of the first piezoelectric devices 100 (see FIG. 1).

In step S122, the sealing material SLb is uniformly formed on the bonding surface M5 of the lid wafer 12W (see FIG. 1). For example, the sealing material SLb, which is made of low-melting-point glass, is formed on the bonding surface M5 of the lid wafer 22W corresponding to the frame portion 102 of the first quartz-crystal frame 10 by screen-printing and then calcinated.

In FIG. 3, step S10 for manufacturing the first quartz-crystal frame 10, step S11 for manufacturing the first base 11, and step S12 for manufacturing the first lid 12 can be carried out separately and in parallel.

In step 5131, as illustrated in FIG. 4, an orientation flat OF is formed at a part of the peripheral edge portion of the quartz-crystal wafer 10W. As illustrated in FIG. 5, an orientation flat OF is also formed at a part of the peripheral edge portion of the base wafer 11W. Accordingly, the quartz-crystal wafer 10W and the base wafer 11W are precisely laminated with reference to the respective orientation flats OF. The sealing material SLa is then heated to approximate temperatures of 350 to 400° C., and the quartz-crystal wafer 10W and the base wafer 11W are pressed. During the heating, the gas released from the electrically conductive adhesive 13 does not remain in the cavity CT, and is discharged to a vacuum chamber (not shown). When the sealing material SLa gradually increases in temperature and begins to melt, the quartz-crystal wafer 10W and the base wafer 11W are then pressed. In this case, the electrically conductive adhesive 13 is enclosed in the spaces 119 surrounded by the sealing material SLa (see FIG. 2A). This process bonds the quartz-crystal wafer 10W and the base wafer 11W together. This also bonds the connecting electrodes 118a and 118b of the base wafer 11W and the extraction electrodes 105a and 105b of the quartz-crystal wafer 10W with the electrically conductive adhesive 13, thus electrically connecting them together. Next, the quartz-crystal vibrating portions 101 are each measured for each vibration frequency.

The vibration frequency is adjusted by changing the thickness (see FIG. 1) of the excitation electrode 104a. Specifically, sputtering metal onto the excitation electrode 104a to increase in mass decreases the frequency. Alternatively, evaporating some metal from the excitation electrode 104a to decrease in mass increases the frequency. If the measured vibration frequency is within a predetermined range, then it is not required to adjust the vibration frequency.

Several hundreds to several thousands of the first quartz-crystal frames 10 are formed on the quartz-crystal wafer 10W. After measurement of the vibration frequency of one quartz-crystal vibrating portion 101 in step S131, the vibration frequency of the one quartz-crystal vibrating portion 101 may be adjusted in step S142. This step is repeated for all the quartz-crystal vibrating portions 101 on the quartz-crystal wafer 10W. In step S131, after measurement of the vibration frequencies of all the quartz-crystal vibrating portions 101 on the quartz-crystal wafer 10W, the vibration frequencies of the quartz-crystal vibrating portions 101 may be adjusted one by one in step S131.

In step S141, the surface M4 (see FIG. 1) of the quartz-crystal wafer 10W bonded to the base wafer 11W and the lid wafer 12W are precisely laminated with reference to the respective orientation flats OF. The laminated wafers are placed in a chamber filled with inert gas (not shown) or in a vacuum chamber (not shown). The laminated wafer has the cavity CT that is also filled with the inert gas or evacuated inside.

Then, the sealing material SLb is heated to approximate temperatures of 350 to 400° C., and then the quartz-crystal wafer 10W and the lid wafer 12W are pressed. During this heating, the gas released from the sealing material SLb does not remain in the cavity CT, and is discharged to a vacuum chamber (not shown). Subsequently, after cooling the sealing material SL to room temperature, the quartz-crystal wafer 10W and the lid wafer 12W are bonded.

In step S142, vibration frequency of the first piezoelectric device 100 is measured. The vibration frequency is adjusted by changing the thickness (see FIG. 1) of the excitation electrode 104a. If the measured vibration frequency is within a predetermined range, then it is not required to adjust the vibration frequency.

In step S143, the bonded quartz-crystal wafers 10W, the base wafers 11W, and the lid wafers 12W are diced into the respective first piezoelectric devices 100. The dicing process uses a dicing device adopting such as a laser beam or a blade to dice into the respective first piezoelectric devices 100 along scribe lines CL that are illustrated by dot-dash lines in FIGS. 4, 5 and 6. This produces several hundreds to several thousands of the first piezoelectric devices 100 with accurately adjusted frequencies.

### Overall Configuration of a Second Piezoelectric Device 110 According to a Second Embodiment

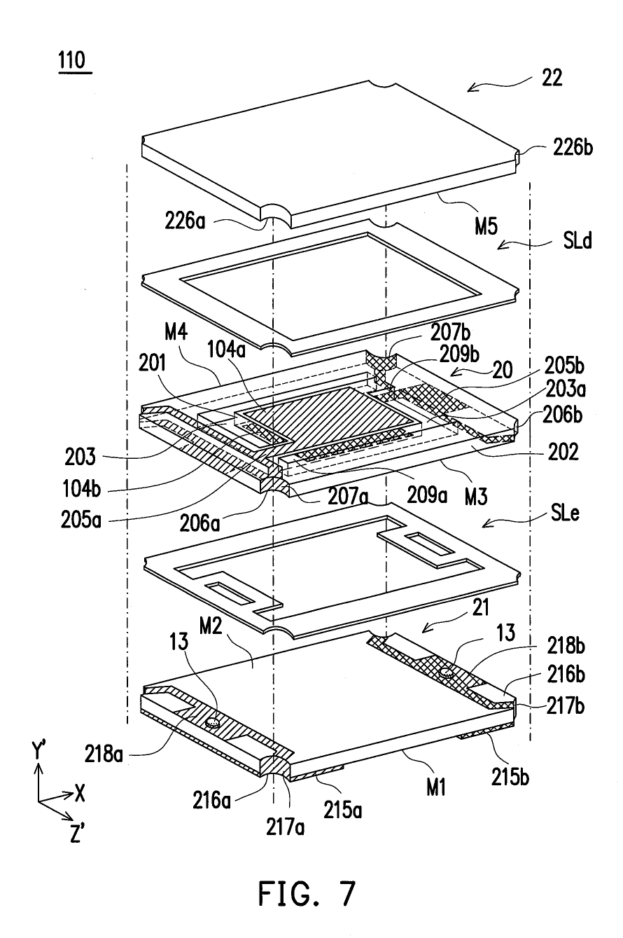

Overall configuration of a second piezoelectric device 110 is described below by referring to FIG. 7. FIG. 7 is an exploded perspective view of the second piezoelectric device 110 from a second lid 22 side.

The second piezoelectric device 110 and the first piezoelectric device 100 have differences in a shape of the castellation and positions and shapes of the connecting electrodes 218a and 218b, which are formed at a second base 21. The second piezoelectric device 110 includes a second quartz-crystal frame 20 instead of the first quartz-crystal frame 10 of the first piezoelectric device 100. Like reference numerals designate corresponding or identical elements to those of the first embodiment throughout FIGS. 7, 8, and 9, and therefore such elements will not be further elaborated here. Differences from the first embodiment are described.

The second piezoelectric device 110 includes the second quartz-crystal frame 20, a second base 21, and a second lid 22. The second base 21 and the second lid 22 are made of quartz-crystal material. The second quartz-crystal frame 20 and the second base 21 are bonded together by the sealing material SLe, while the second quartz-crystal frame 20 and the second lid 22 are bonded together by the sealing material SLd. The cavity CT (not shown) is in a vacuum state or filled with inert gas.

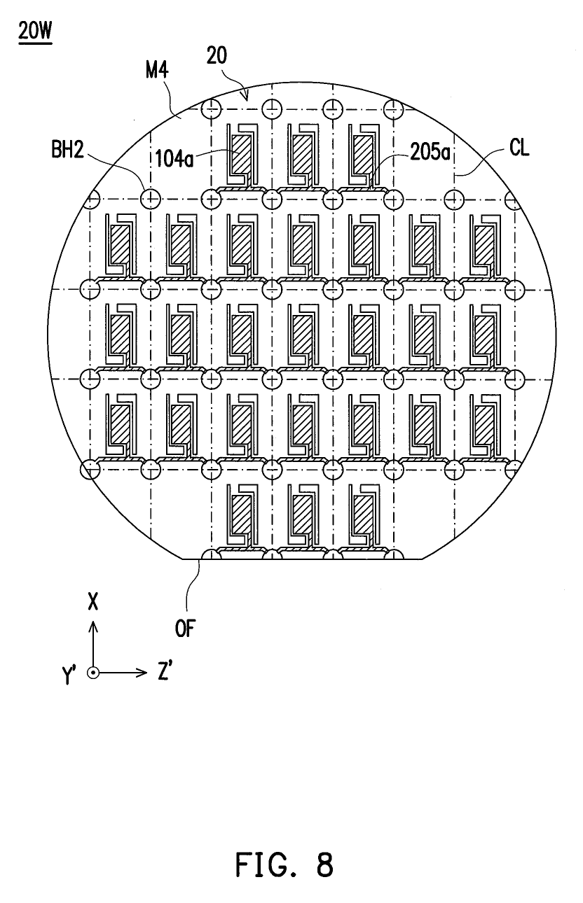

The second quartz-crystal frame 20 includes a crystalline bonding surface M3 and a crystalline bonding surface M4. The second quartz-crystal frame 20 includes a frame portion 202 that surrounds the quartz-crystal vibrating portion 201. Extraction electrodes 205a and 205b, which are electrically connected to excitation electrodes 104a and 104b, are formed on both the surfaces of the frame portion 202. Further, quartz-crystal castellations 206a and 206b are formed on four corners of the second quartz-crystal frame 20. Quartz-crystal side-surface electrodes 207a and 207b, which are connected to the respective extraction electrodes 205a and 205b, are formed at the pair of the quartz-crystal castellations 206a and 206b. The quartz-crystal castellations 206a and 206b are formed when circular through-holes BH2 are diced (see FIG. 8).

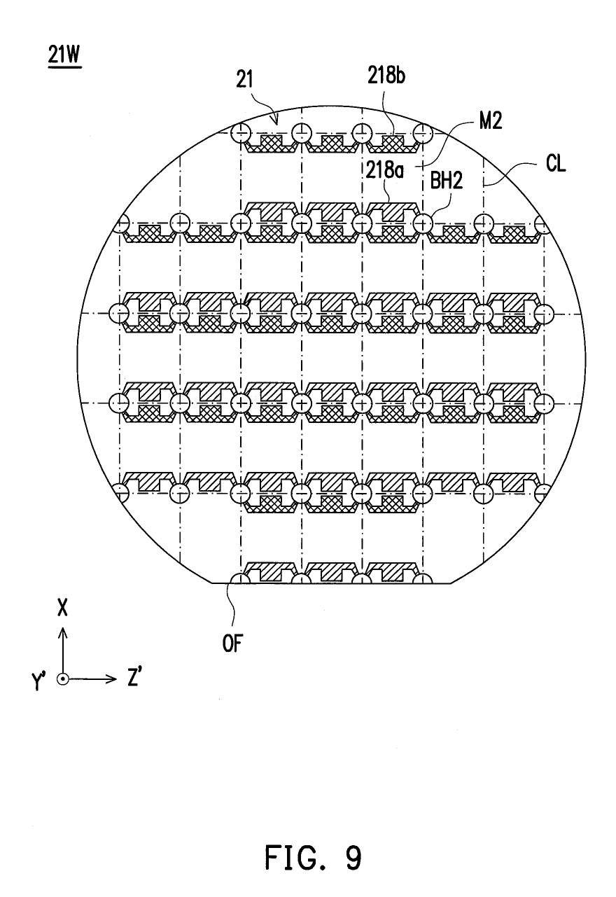

The second base 21 includes a mounting surface M1 and a bonding surface M2. A pair of external electrodes 215a and 215b are each formed on the mounting surface M1 of the second base 21. A pair of castellations 216a and 216b are each formed at the four corners of the second base 21. At the castellation 216a, a side-surface electrode 217a, which are connected to the external electrode 215a and a connecting electrode 218a, are formed. At the castellation 216b, a side-surface electrode 217b, which are connected to the external electrode 215b and a connecting electrode 218b, are formed. The castellations 216a and 216b are formed when the circular through-holes BH2 are diced (see FIG. 9).

The second lid 22 includes a bonding surface M5. A pair of castellations 226a and 226b are formed at the four corners of the second lid 22. The castellations 226a and 226b are formed when the circular through-holes BH2 (not shown) are diced.

A method for Manufacturing the Second Piezoelectric Device 110

A method for manufacturing the second piezoelectric device 110 illustrated in FIG. 7 is substantially the same as the method of the flowchart in FIG. 3 described in the first embodiment except as described below. FIG. 8 is a plan view of a quartz-crystal wafer 20W. FIG. 9 is a plan view of a base wafer 21W. Differences of the methods are described using the flowchart in FIG. 3.

The method for manufacturing the second piezoelectric device 110 is described using steps of the flowchart in FIG. 3. In step S101 for manufacturing the second quartz-crystal frame 20, step S111 for manufacturing the second base 21, and step S121 for manufacturing the second lid 22, the circular through-holes BH2 are formed.

In step S101, when outlines of a plurality of second quartz-crystal frames 20 are formed by etching, the circular through-holes BH2 are formed to pass through the quartz-crystal wafer 20W at the four corners of respective second quartz-crystal frames 20 as illustrated in FIG. 8. Here, each of the quarterly divided circular through-holes BH2 provides one of the castellations 206a and 206b for each of the second piezoelectric devices 110 (see FIG. 7).

In step S111, the circular through-holes BH2 are formed to pass through the base wafer 21W at the four corners of the respective second bases 21 as illustrated in FIG. 9. Here, each of the quarterly divided circular through-holes BH2 provides one of the castellations 216a and 216b for each of the second piezoelectric devices 110 (see FIG. 7).

In step 5121, the circular through-holes BH2 (not shown) are formed to pass through the lid wafer 22W at the four corners of the respective second lid 22. Here, each of the quarterly divided circular through-holes BH2 provides one of the castellations 226a and 226b for each of the second piezoelectric devices 110 (see FIG. 7).

In step S104, the sealing material SLe is uniformly formed on the surface M3 (see FIG. 7) of the frame portion 202 on the quartz-crystal wafer 20W (see FIG. 8). For example, the sealing material SLe, which is made of low-melting-point glass, is formed on the surface M3 of the frame portion 202 on the quartz-crystal wafer 20W by screen-printing and calcinated. The sealing material SLe may be formed on the surface M2 on the base wafer 21W (see FIG. 7).

In step S113, the external electrodes 215a and 215b are formed on the mounting surface M1 of the base wafer 21W. The side-surface electrodes 217a and 217b are formed at the circular through-hole BH2. Then, the connecting electrodes 218a and 218b (see FIG. 9) are formed on the base bonding surface M2.

In step S114, the electrically conductive adhesive 13 is placed at the connecting electrodes 218a and 218b of the base wafer 21W, and then calcinated. Gas released from the electrically conductive adhesives 13 is eliminated by the calcination.

In step S122, the sealing material SLd is uniformly formed on the bonding surface M5 (see FIG. 7) of the lid wafer 22W. The sealing material SLd, which is made of low-melting-point glass, is formed on the bonding surface M5 of the lid wafer 22W corresponding to the frame portion 202 of the second quartz-crystal frame 20 by screen-printing and calcinated. The processes after step S131 are substantially the same as those in the flowchart (see FIG. 3) described in the first embodiment.

### Configuration of a Third Piezoelectric Device 120 According to a Third Embodiment

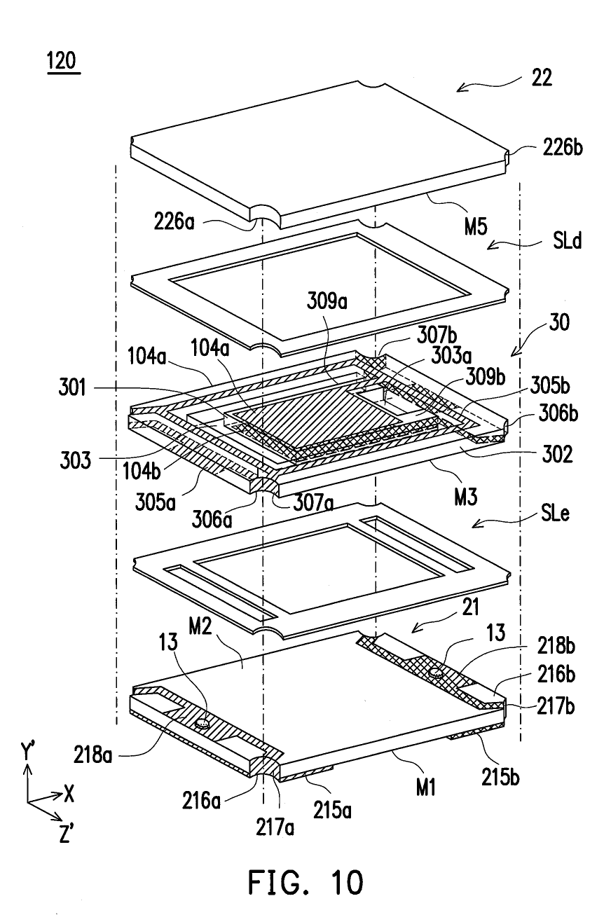

Overall configuration of the third piezoelectric device 120 is described below by referring to FIG. 10. FIG. 10 is an exploded perspective view of the third piezoelectric device 120 from the second lid 22 side.

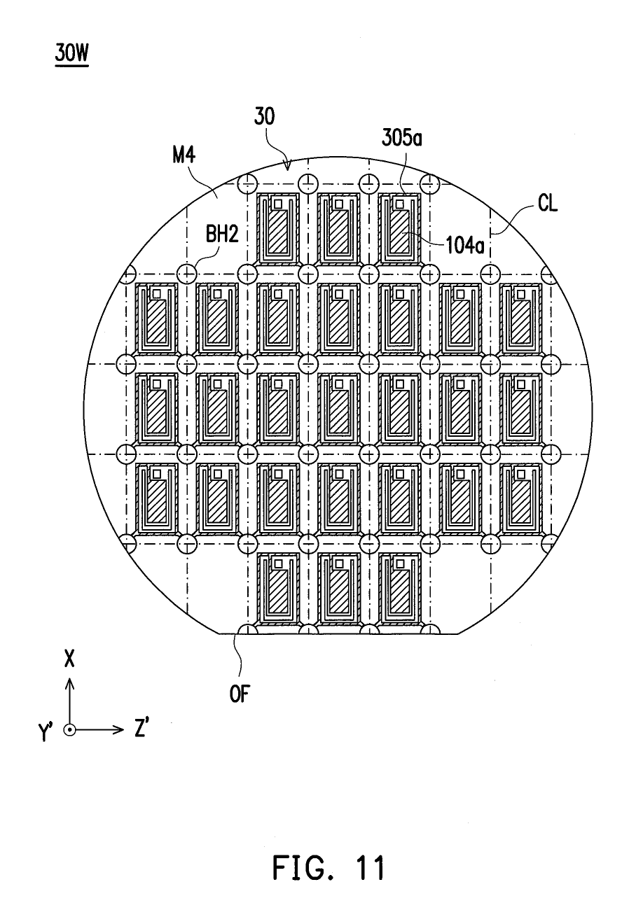

The third piezoelectric device 120 is different from the second piezoelectric device 110 in that the third piezoelectric device 120 includes the third quartz-crystal frame 30 instead of the second quartz-crystal frame 20 of the second piezoelectric device 110. Like reference numerals designate corresponding or identical elements throughout FIGS. 10 and 11, and therefore such elements will not be further elaborated here. Differences from the second embodiment are described.

The third piezoelectric device 120 includes a third quartz-crystal frame 30, the second base 21, and the second lid 22. The second base 21 and the second lid 22 are made of quartz-crystal material. The third quartz-crystal frame 30 and the second base 21 are bonded together by the sealing material SLf, while the third quartz-crystal frame 30 and the second lid 22 are bonded together by the sealing material SLd. The cavity CT (not shown) is in vacuum state or filled with inert gas.

The third quartz-crystal frame 30 includes the crystalline bonding surface M3 and the crystalline bonding surface M4. The third quartz-crystal frame 30 includes a frame portion 302 that surrounds the quartz-crystal vibrating portion 301. Extraction electrodes 305a and 305b, which are electrically connected to excitation electrodes 104a and 104b, are formed on both the surfaces of the frame portion 302. Further, quartz-crystal castellations 306a and 306b are formed at four corners of the third quartz-crystal frame 30. Respective quartz-crystal side-surface electrodes 307a and 307b, which are respectively connected to the extraction electrodes 305a and 305b, are formed at a pair of the quartz-crystal castellations 306a and 306b. The quartz-crystal castellations 306a and 306b are formed when circular through-holes BH2 are diced (see FIG. 11).

The third quartz-crystal frame 30 includes an AT-cut quartz crystal vibrating portion 301. A pair of the excitation electrodes 104a and 104b are placed on both main surfaces adjacent to the center of the quartz crystal vibrating portion 301, facing each other. The excitation electrode 104a is connected to the extraction electrode 305a that extends to an end side in the −X axis direction at the bottom face (in the −Y′ axis direction) of the frame portion 302. The excitation electrode 104b is connected to the extraction electrode 305b that extends to an end side in the +X axis direction at the bottom face (in the −Y′ axis direction) of the frame portion 302. The extraction electrode 305a is formed at the one end in the X axis direction on the surface M3 (see FIG. 10), while the extraction electrode 305b is formed at the other end in the X axis direction on the surface M3. The third quartz-crystal frame 30 is bonded to the connecting electrode 218a and the connecting electrode 218b of the second base 21 by the electrically conductive adhesives 13 (not shown).

A method for Manufacturing the Third Piezoelectric Device 120

A method for manufacturing the third piezoelectric device 120 illustrated in FIG. 10 is substantially the same as the method of the flowchart in FIG. 3 described in the first embodiment except as described below. FIG. 11 is a plan view of the quartz-crystal wafer 30W. Differences of the methods are described using the flowchart in FIG. 3.

In step S101, when outlines of a plurality of the third quartz-crystal frames 30 are formed by etching, the circular through-holes BH2 are formed to pass through the quartz-crystal wafer 30W at the four corners of respective third quartz-crystal frames 30 as illustrated in FIG. 11. Here, each of the quarterly divided circular through-holes BH2 provides one of the castellations 306a and 306b for each of the second piezoelectric devices 120 (see FIG. 10).

In step S104, the sealing material SLf is uniformly formed on the surface M3 (see FIG. 10) of the frame portion 302 on the quartz-crystal wafer 30W (see FIG. 11). For example, the sealing material SLf, which is made of low-melting-point glass, is formed on the surface M3 of the frame portion 302 on the quartz-crystal wafer 30W by screen-prinfing and calcinated. The sealing material SLf may be formed on the surface M2 of the base wafer 21W (see FIG. 10). The subsequent processes are substantially the same as those in the flowchart (see FIG. 3) described in the first embodiment.

Representative embodiments have been described in detail above. As evident to those skilled in the art, the present invention may be changed or modified in various ways within the technical scope of the invention. For example, while an AT-cut quartz crystal piece is used in the embodiments, the present invention may be directed to a tuning-fork type vibrating piece that has a pair of vibrating pieces. While a quartz crystal piece is used in the embodiments, piezoelectric material other than crystal such as lithium tantalite and lithium niobate may be used. Further, the present invention may be applied to a piezoelectric oscillator that has an IC including an oscillating circuit mounted inside the package as a piezoelectric device.

What is claimed is:

1. A piezoelectric device comprising:
a piezoelectric vibrating plate including a piezoelectric vibrating piece, a frame body, and a pair of extraction electrodes, the piezoelectric vibrating piece including a pair of excitation electrodes, the frame body surrounding the piezoelectric vibrating piece, the frame body being formed integrally with the piezoelectric vibrating piece, the frame body including a first main surface and a second main surface, the pair of extraction electrodes being extracted from the pair of excitation electrodes to the first main surface of the frame body;
a first plate including a first surface and a second surface, the first surface including a pair of external electrodes, the second surface including a pair of connecting electrodes, the pair of connecting electrodes being electrically connected to the pair of the external electrodes, the second surface bonding to the first main surface;
a first glass sealing material disposed in a ring shape, to enclose a periphery of the first main surface of the frame body so as to bond the first plate and the first main surface of the frame body together; and
an electrically conductive adhesive that electrically connects the pair of the extraction electrodes to the pair of the connecting electrodes.

2. The piezoelectric device of claim 1, wherein
the frame body has a rectangular shape with four sides, and
the glass sealing material is arranged to surround the electrically conductive adhesive within a width of one of the four side at the frame body.

3. The piezoelectric device of claim 1, further comprising:
a castellation recessed toward a center of the first plate, the castellation being on a side face, the side face being connected between the first surface and the second surface; and
a pair of side-surface electrodes disposed at the castellation, the pair of side-surface electrodes electrically connecting the pair of the external electrodes to the pair of the connecting electrodes.

4. The piezoelectric device of claim 2, further comprising:
a castellation recessed toward a center of the first plate, the castellation being on a side face, the side face being connected between the first surface and the second surface; and
a pair of side-surface electrodes disposed at the castellation, the pair of side-surface electrodes electrically connecting the pair of the external electrodes to the pair of the connecting electrodes.

5. The piezoelectric device of claim 1, further comprising:
a second plate bonded to the second main surface to hermetically enclose the piezoelectric vibrating piece; and
a second glass sealing material in a ring shape, to enclose a periphery of the second main surface of the frame body so as to bond the second plate and the second the main surface of the frame body together.

6. The piezoelectric device of claim 2, further comprising:
a second plate bonded to the second main surface to hermetically enclose the piezoelectric vibrating piece; and
a second glass sealing material in a ring shape, to enclose a periphery of the second main surface of the frame body so as to bond the second plate and the second the main surface of the frame body together.

7. The piezoelectric device of claim 3, further comprising:
a second plate bonded to the second main surface to hermetically enclose the piezoelectric vibrating piece; and
a second glass sealing material in a ring shape, to enclose a periphery of the second main surface of the frame body so as to bond the second plate and the second the main surface of the frame body together.

8. The piezoelectric device of claim 4, further comprising:
a second plate bonded to the second main surface to hermetically enclose the piezoelectric vibrating piece; and
a second glass sealing material in a ring shape, to enclose a periphery of the second main surface of the frame body so as to bond the second plate and the second the main surface of the frame body together.

9. The piezoelectric device of claim 1, wherein the piezoelectric vibrating piece includes a piezoelectric vibrating piece with a thickness-shear vibration mode.

10. A method for manufacturing the piezoelectric device of claim 1, comprising:
preparing a piezoelectric wafer, the piezoelectric wafer including a plurality of piezoelectric vibrating plates, the piezoelectric vibrating plate including a piezoelectric vibrating piece, a frame body, and a pair of extraction electrodes, the piezoelectric vibrating piece including a pair of excitation electrodes, the frame body surrounding the piezoelectric vibrating piece, the frame body being formed integrally with the piezoelectric vibrating piece, the frame body including a first main surface and a second main surface, the pair of extraction electrodes being extracted from the pair of excitation electrodes to the first main surface of the frame body;
preparing a first wafer, the first wafer including a plurality of first plates, the first plate including a first surface and a second surface, the first surface including a pair of external electrodes, the second surface including a pair of connecting electrodes, the second surface being at an opposite side of the first surface, the first wafer including a through-hole and a side-surface electrode, the through-hole passing through the first surface and the second surface between the adjacent first plates, the side-surface electrode electrically connecting the external electrodes to the connecting electrodes at the through-hole;
applying first glass sealing material on at least one of the frame body and a peripheral area of the first plate;
calcinating the applied first glass sealing material;
applying electrically conductive adhesive on at least one of the extraction electrodes and the connecting electrodes after the calcinating; and
bonding the piezoelectric wafer and the first wafer together after the applying the electrically conductive adhesive.

11. The method of claim 10, wherein
the frame body has a rectangular shape with four sides, and
the applying glass sealing material applies the glass sealing material so as to surround a region to which the electrically conductive adhesive is to be applied within a width of one of the side four sides.

12. The method of claim 10, further comprising
calcinating the electrically conductive adhesive after the applying electrically conductive adhesive and before the bonding of the piezoelectric wafer and the first wafer.

13. The method of claim 11, further comprising calcinating the electrically conductive adhesive after the applying electrically conductive adhesive and before the bonding of the piezoelectric wafer and the first wafer.

14. The method of claim 10, further comprising:
preparing a second wafer, the second wafer including a plurality of second plates;
applying a second glass sealing material over at least one of a peripheral area of the frame body and the second plate;
calcinating the applied glass sealing material; and
bonding the piezoelectric wafer and the second wafer together after bonding the piezoelectric wafer and the first wafer.

15. The method of claim 11, further comprising:
preparing a second wafer, the second wafer including a plurality of second plates;
applying second glass sealing material over at least one of a peripheral area of the frame body and the second plate;
calcinating the applied second glass sealing material; and
bonding the piezoelectric wafer and the second wafer together after bonding the piezoelectric wafer and the first wafer.

16. The method of claim 12, further comprising:
preparing a second wafer, the second wafer including a plurality of second plates;
applying a second glass sealing material over at least one of a peripheral area of the frame body and the second plate;
calcinating the applied second glass sealing material; and
bonding the piezoelectric wafer and the second wafer together after bonding the piezoelectric wafer and the first wafer.

17. The method of claim 13, further comprising:
preparing a second wafer, the second wafer including a plurality of second plates;
applying a second glass sealing material over at least one of a peripheral area of the frame body and the second plate;
calcinating the applied second glass sealing material; and
bonding the piezoelectric wafer and the second wafer together after bonding the piezoelectric wafer and the first wafer.
